(19) United States
(12) Patent Application Publication
(10) Pub. No.: US 2026/0239612 A1
(43) Pub. Date: Aug. 13, 2026

(54) SEMICONDUCTOR DEVICE AND METHOD OF FABRICATING THE SAME

(71) Applicant: Fujian Jinhua Integrated Circuit Co., Ltd., Quanzhou City (CN)

(72) Inventors: Hangle Guo, Quanzhou City (CN); Feng-Nien Tsai, Quanzhou City (CN); Li-Wei Feng, Quanzhou City (CN)

(73) Assignee: Fujian Jinhua Integrated Circuit Co., Ltd., Quanzhou City (CN)

(21) Appl. No.: 19/455,786

(22) Filed: Jan. 21, 2026

(30) Foreign Application Priority Data
Feb. 8, 2025 (CN) 202510142071.3

(51) Int. Cl. H10B 12/00

(52) U.S. Cl. CPC H10B 12/50; H10B 12/34; H10B 12/482; H10B 12/053; H10B 12/09

(57) ABSTRACT

The present disclosure provides a semiconductor device and a method of fabricating the same, and the semiconductor device includes a substrate, at least two gate structures, a first spacer structure, and a second spacer structure. The at least two gate structures are disposed on the substrate and each includes a short side extending in a first direction and a long side extending in a second direction. The short side of each of the at least two gate structures is opposite with each other. The first spacer structure covers the long side of each of the at least two gate structures. The second spacer structure covers the short side of each of the at least two gate structures, wherein an extending length of the second spacer structure is longer than an extending length of the short side of each of the at least two gate structures.

### CROSS REFERENCE TO RELATED APPLICATION

This application claims the benefit of Chinese Patent Application No. 202510142071.3 filed on Feb. 8, 2025, which is incorporated herein by reference.

### BACKGROUND OF THE INVENTION

### 1. Field of the inventor

The present invention generally relates to a semiconductor device and a method of fabricating the same, and more particularly to a semiconductor device having a gate structure and a method of fabricating the same.

### 2. Description of the prior art

With the trend of miniaturization of various electronic products, semiconductor devices must be designed to meet the requirements of high integration and high density. For a dynamic random access memory (DRAM) with a trench gate structure, due to its advantage of having enlarged carrier channel length in common semiconductor substrate area so as to reduce current leakage in the capacitor structure, it has gradually replaced dynamic random access memory devices with planar gate structures under current development trend. Generally, a dynamic random access memory with a trench gate structure is an array area formed by a large number of memory cells for data storage. Each memory cell can be composed of transistor components and capacitor components in series to receive voltage data from word lines (WL) and bit lines (BL). With the increasing product requirements, higher and higher density of memory cells in the array area is also required, resulting in increasing difficulty and complexity in related manufacturing processes and designs. Therefore, conventional technologies or structures need to be improved to enhance efficiency and reliability of related memory devices.

### SUMMARY OF THE INVENTION

An object of the present invention is to provide a semiconductor device, in which various spacer structures having different materials and/or different films are respectively disposed on different sides of a gate structure, such that, the gate structure may achieve various isolating functions in different extending directions. In this way, the semiconductor device of the present invention will therefore gain better structure and efficiency, so as to improve the operating performance of the semiconductor device.

An object of the present invention is to provide a method of forming a semiconductor device, where various spacer structures having different materials and/or different films are respectively formed on different sides of a gate structure, such that, the gate structure may achieve various isolating functions in different extending directions. In this way, the semiconductor device being formed through the method of the present invention will therefore gain better structure and efficiency, to achieve an improved operating performance thereof.

For achieving the above-described object, according to an embodiment of the present invention, a semiconductor device including a substrate, at least two gate structures, a first spacer structure, and a second spacer structure. The at least two gate structures are disposed on the substrate and each includes a short side extending in a first direction and a long side extending in a second direction. The short side of the at least two gate structures is opposite with each other. The first direction is perpendicular to the second direction. The first spacer structure covers the long side of each of the at least two gate structures. The second spacer structure covers the short side of each of the at least two gate structures, wherein an extending length of the second spacer structure is longer than an extending length of the short side of each of the at least two gate structures.

For achieving the above-described object, according to an embodiment of the present invention, a method of fabricating a semiconductor device is provided including the following steps. Firstly, a substrate is provided, and at least two gate structures are formed on the substrate, with each including a short side extending in a first direction and a long side extending in a second direction. The short side of the at least two gate structures is opposite with each other. The first direction is perpendicular to the second direction. The first spacer structure is formed on the long side of each of the at least two gate structures. The second spacer structure is formed on the short side of each of the at least two gate structures, wherein an extending length of the second spacer structure in the first direction is longer than an extending length of the short side of each of the at least two gate structures in the first direction.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are directed to provide a better understanding of the embodiments and are included as parts of the specification of the present disclosure. These drawings and descriptions are used to illustrate the principles of the embodiments. It should be noted that all drawings are schematic, and the relative dimensions and scales have been adjusted for the convenience of drawing. Identical or similar features in different embodiments are marked with identical symbols.

FIG. 1 to FIG. 5 are schematic diagrams illustrating a semiconductor device according to a first embodiment of the present invention, wherein:

FIG. 1 is a top view of a semiconductor device;

FIG. 2 is a cross-sectional view of a semiconductor device taken along cross-lines A-A’ and B-B’ in FIG. 1;

FIG. 3 is a local diagram of a spacer structure and a gate structure in FIG. 1;

FIG. 4 is another cross-sectional view of a semiconductor device taken along cross-lines A-A’ and B-B’ in FIG. 1; and

FIG. 5 is another cross-sectional view of a semiconductor device taken along cross-lines A-A’ and B-B’ in FIG. 1.

FIG. 6 to FIG. 8 are schematic diagrams illustrating a method of forming a semiconductor device according to a preferred embodiment of the present invention, wherein:

FIG. 6 is a top view illustrating a semiconductor device after forming a stacked layer structure;

FIG. 7 is a top view illustrating a semiconductor device after forming a patterning process; and

FIG. 8 is a top view illustrating a semiconductor device after forming a spacer structure.

FIG. 9 to FIG. 10 are schematic diagrams illustrating a semiconductor device according to a second embodiment of the present invention, wherein:

FIG. 9 is a top view of a semiconductor device; and

FIG. 10 is a local diagram of a spacer structure and a gate structure in FIG. 9.

FIG. 11 to FIG. 12 are schematic diagrams illustrating a semiconductor device according to a third embodiment of the present invention, wherein:

FIG. 11 is a top view of a semiconductor device; and

FIG. 12 is a local diagram of a spacer structure and a gate structure in FIG. 11.

### DETAILED DESCRIPTION

For better understanding of the presented disclosure, preferred embodiments will be described in detail. The preferred embodiments of the present disclosure are illustrated in the accompanying drawings with numbered elements. In addition, the technical features in different embodiments described in the following may be replaced, recombined, or mixed with one another to constitute another embodiment without departing from the spirit of the present disclosure.

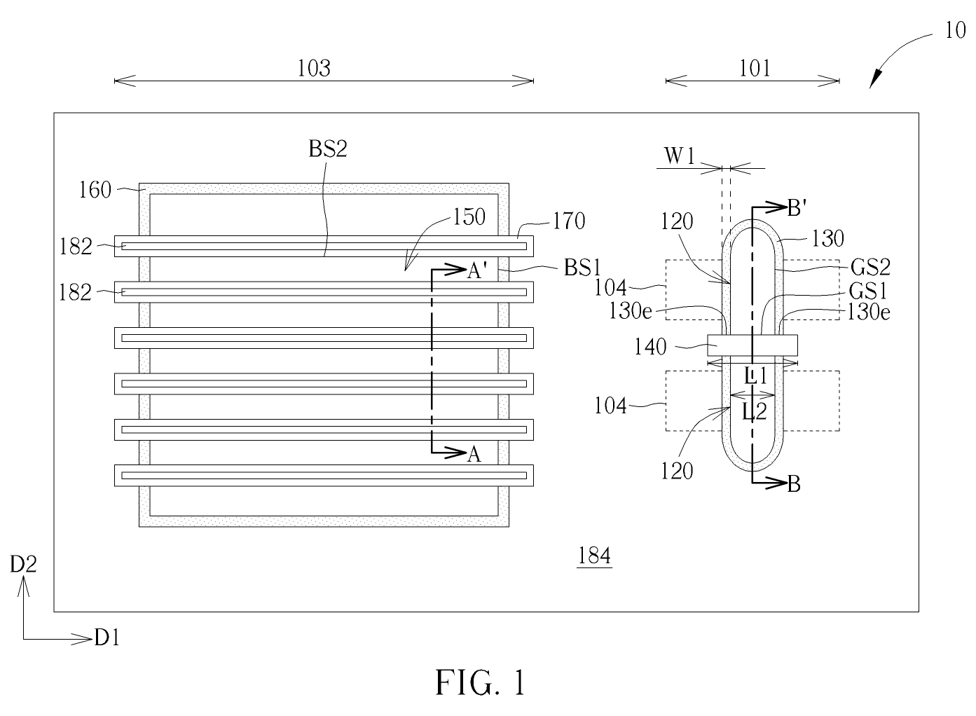

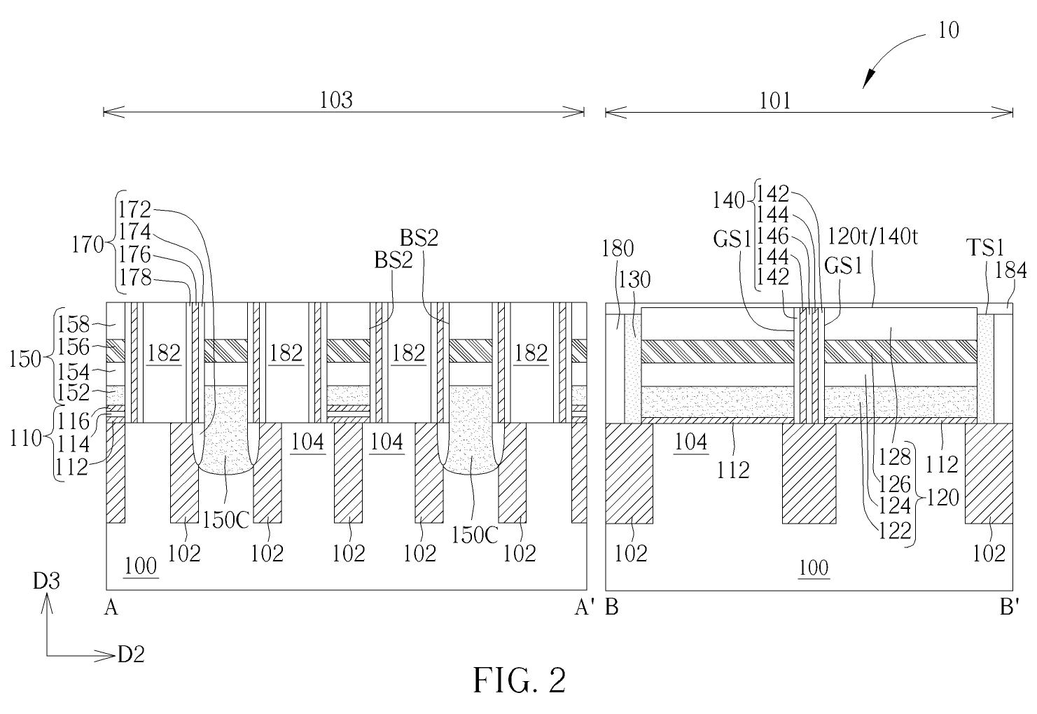

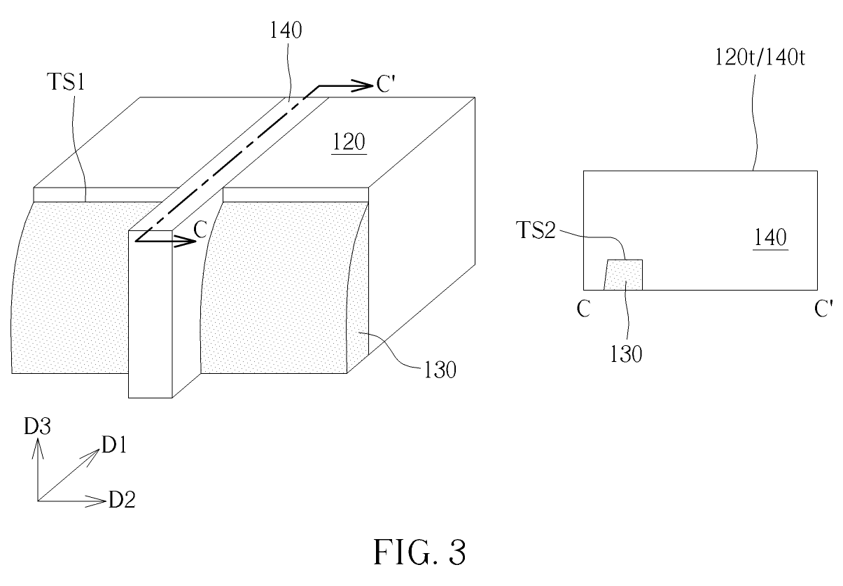

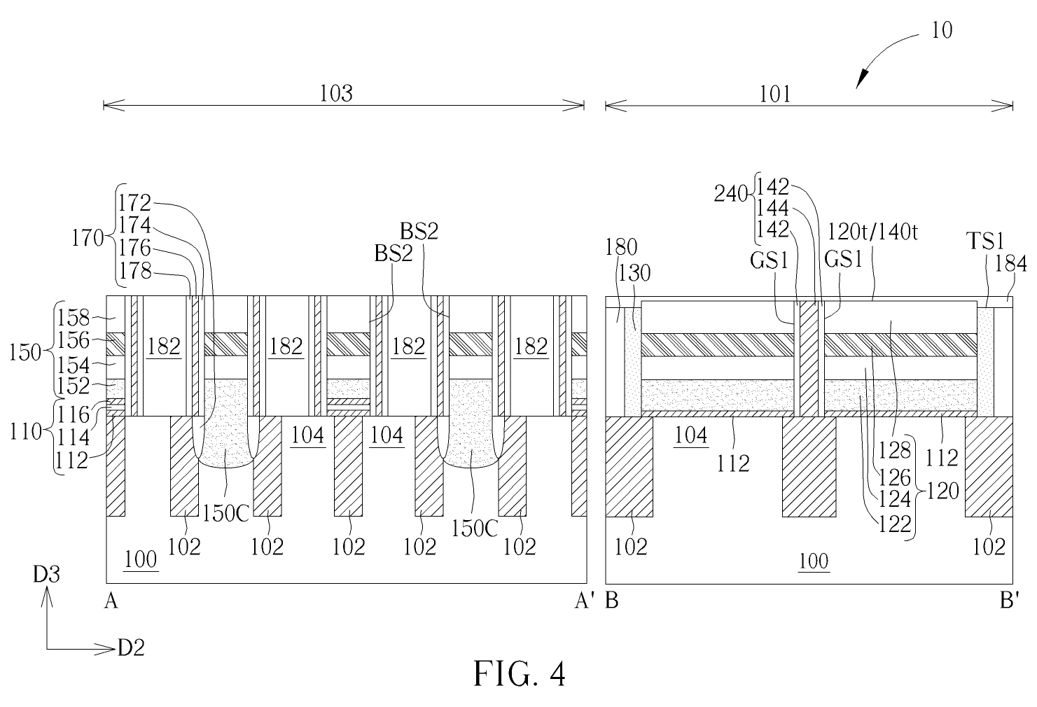

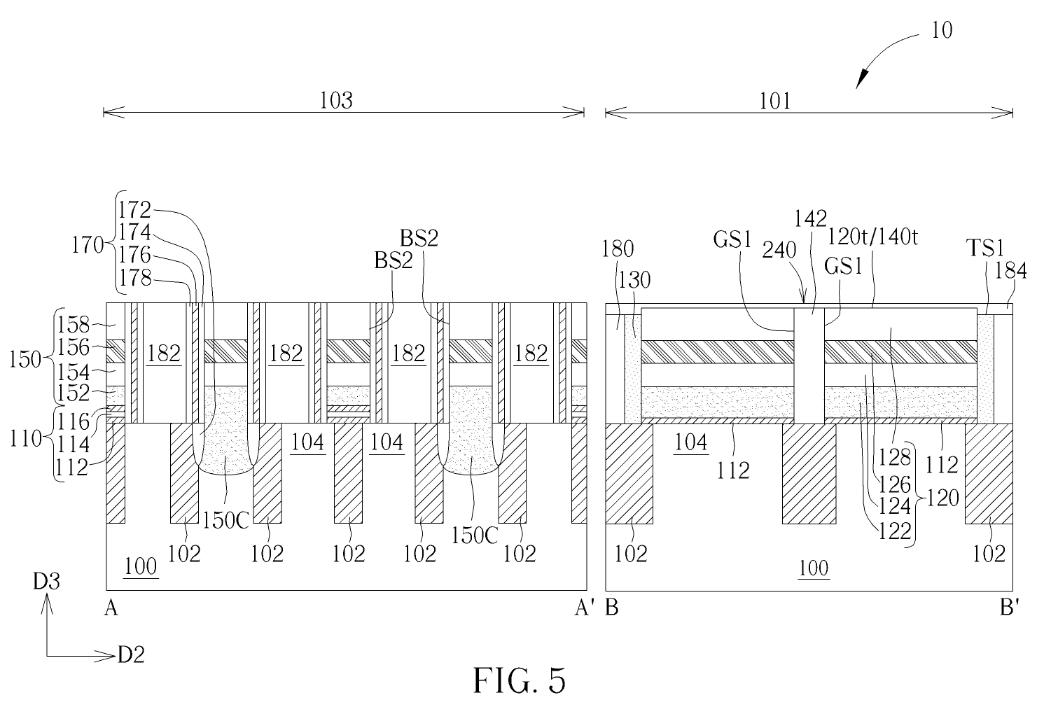

Please refer to FIG. 1 to FIG. 5, which are schematic diagrams illustrating a semiconductor device 10 according to a first embodiment of the present invention, in which FIG. 1 illustrates a top view of the semiconductor device 10, FIG. 2, FIG. 4, and FIG. 5 respectively illustrate a cross-sectional view of the semiconductor device 10, and FIG. 3 illustrates a partial three-dimensional view and a partial cross-sectional view of the semiconductor device 10. Firstly, as shown in FIG. 1 and FIG. 2, the semiconductor device 10 includes a substrate 100, at least two gate structures 120 disposed on the substrate 100, and a first spacer structure 130 and a second spacer structure 140 disposed on the at least two gate structures 120. The substrate 100 for example includes a silicon substrate, a silicon-containing substrate, or a silicon-on-insulator substrate, and a cell region 103 having related higher component integration, and a peripheral region 101 having related lower component integration, are both defined on the substrate 100. In one embodiment, the cell region 103 and the peripheral region 101 are for example disposed adjacent to each other, but not limited thereto. Also, at least one shallow trench isolation (STI) 102 as shown in FIG. 2 is disposed within the substrate 100, to define a plurality of active areas (AAs) 104 in the substrate 100, respectively within the peripheral region 101 and the cell region 103.

The two gate structures 120 are disposed within the peripheral region 101, and each includes a short side GS1 extending in a first direction D1, and two long sides GS2 extending in a second direction D2. The short side GS1 of one of the two gate structures 120 is opposite to the short side GS1 of another one of the two gate structures 120 in the second direction D2, and the short sides GS1 of the two gate structure 120 are namely adjacent with each other, as shown in FIG. 1. It is noted that, the first spacer structure 130 completely covers the long sides GS2 of the two gate structures 120, and the second spacer structure 140 is disposed between the two gate structures 120, with the short side GS1 of the two gate structures 120 being covered by the second spacer structure 140 at the same time. An extending length L1 of the second spacer structure 140 in the first direction D1 is longer than an extending length L2 of the short side GS1 of each gate structure 120 in the first direction D1. In one embodiment, the second spacer structure 140 intersects the first spacer structure 130 disposed on the two long sides of each gate structure 120, such that, the extending length L1 is preferably longer than a sum of the extending length L2 and two times of a weight W1 of the first spacer structure 130 on each long side GS2 in the first direction D1, as shown in FIG. 1, but not limited thereto. Accordingly, through arranging the first spacer structure 130 and the second spacer structure 140 on the gate structures 120, it is efficiency to isolate the contact between different sides of each gate structure 120 from any adjacent component in various directions, so as to achieve different isolating effects in different extension directions of each gate structure 120. With these arrangements, the semiconductor device 10 enables to gain an improved component structure and better function, thereby providing better performance.

In one embodiment, the first spacer structures 130 respectively disposed on the long sides GS2 of the two gate structures 120 is separately from each other, in the second direction D2. In other words, the first spacer structure 130 disposed on each long side GS2 of each gate structure 120 includes an end portion 130e in the first direction D1, and the second spacer structure 140 covers each end portion 130e of the first spacer structure 130 at the same time, so that, the first spacer structures 130 disposed on the long sides GS2 of the two gate structures 120 are not in direct contact with each other. In another embodiment, as shown in FIG. 3, the first spacer structure 130 disposed on the long sides GS2 of each gate structure 120 is partially disposed below the second spacer structure 140, such that the first spacer structures 130 disposed on the long sides GS2 of the two gate structures 120 may be in direct contact with each other under the second spacer structure 140. Also, due to the difference in etching selectivity, the first spacer structure 130 may have a first surface TS1 and a second surface TS2 with different heights in a vertical direction D3 perpendicular to the substrate 100. The second surface TS2 of the first spacer structure 130 is disposed between the two gate structures 120, and below the second spacer structure 140, and which will be entirely covered by the second spacer structure 140. The first surface TS1 of the first spacer structure 130 is disposed at a place being not covered by the second spacer structure 140. It is noted that, the first surface TS1 is higher than the second surface TS2 and is slightly lower than a top surface 140t of the second spacer structure 140 or a top surface 120t of the gate structures 120, as shown in FIG. 3.

Further in view of FIG. 1 and FIG. 2, the semiconductor device further includes a plurality of bit line structures 140, a first bit line spacer structure 160 and a second bit line spacer structure 170. The bit line structures 150 are for example separately extended in the first direction D1, with each of the bit line structures 150 further including two first sidewalls BS1 extending in the second direction D2 and two second sidewalls BS2 extending in the first direction D1.

The two first sidewalls BS1 of each bit line structure 150 are oppositely arranged in the first direction D1, and the two second sidewalls BS2 of each bit line structure 150 are oppositely arranged in the second direction D2. The first bit line spacer structure 160 completely covers the two first sidewalls BS1 of each bit line structure 150, and the second bit line spacer structure 170 completely covers the two second sidewalls BS2 of each bit line structure 150. Likewise, through arranging the first bit line spacer structure 160 and the second bit line spacer structure 170, it is efficiency to isolate the contact between different sides of each bit line structure 150 from any adjacent component in various directions, so as to achieve different isolating effects in different extension directions of each bit line structure 150.

Precisely speaking, the bit line structures 150 are disposed on a dielectric layer 110, and each further includes a semiconductor layer 152 (including a semiconductor material like doped polysilicon and doped amorphous silicon), a barrier layer 154 (including a conductive barrier materials like titanium and/or titanium nitride, tantalum and/or tantalum oxide), a metal layer 156 (including a low resistance metal material like tungsten, aluminum or copper) and a capping layer 158 (including an insulating material like silicon nitride, silicon carbonitride or silicon oxynitride) stacked in sequence. Each of the bit line structures 150 extends into the substrate through a bit line contact (BLC) 150C being formed correspondingly, underneath, to electrically connect to the corresponding active area 104 within the cell region 103. In one embodiment, the dielectric layer 110 for example includes a silicon oxide layer 112, a silicon nitride layer 114 and a silicon oxide layer 116 stacked in sequence to result in an oxide-nitride-oxide (ONO) structure, but it is not limited thereto. It is noted that, the formation of the gate structures 120 within the peripheral region 101 is for example integrated with the process of the bit lines 150 within the cell region 103, such that, each gate structure 120 will therefore include similar components and similar materials as that of each bit line structure 150. In other words, each gate structure 120 within the peripheral region 101 is for example disposed on the silicon oxide layer 112, and which also includes a semiconductor layer 122 (including a semiconductor material like doped polysilicon and doped amorphous silicon), a barrier layer 124 (including a conductive barrier materials like titanium and/or titanium nitride, tantalum and/or tantalum oxide), a metal layer 126 (including a low resistance metal material like tungsten, aluminum or copper) and a capping layer 128 (including an insulating material like silicon nitride, silicon carbonitride or silicon oxynitride) stacked in sequence, but not limited thereto. In another embodiment, the formation of the gate structure may be optionally not integrated with the process of the bit line structures, and which may include a metal gate structure or other suitable gate structure.

On the other hand, the formation of the first spacer structure 130 on the long side GS2 of each gate structure 120 may also be optionally integrated with the process of the first bit line spacer structure 160 on the first sidewall BS1 of each bit line structure 150, so that, the first spacer structure 130 may include similar components and similar materials as that of the first bit line spacer structure 160. For example, the first bit line spacer structure 160 and the first spacer structure 130 for example includes a monolayer structure as shown in FIG. 1, including an insulating material like silicon oxide, silicon oxynitride, silicon nitride or silicon carbonitride, but not limited thereto. In another embodiment, the first bit line spacer structure and the first spacer structure may optionally include a multilayer structure having similar components and similar materials. The formation of the second spacer structure 140 on the short side GS1 of each gate structure 120 may also be integrated with the process of the second bit line spacer structure 170 on the second sidewall BS2 of each bit line structure 150, so that, the second spacer structure 140 and the second bit line spacer structure 170 will therefore include similar components and similar materials, but not limited thereto.

In one embodiment, the second bit line spacer structure 170 for example includes a first bit line spacer 172 (for example including silicon nitride or silicon carbonitride) disposed on the sidewall of each bit line contact 150C, and a second bit line spacer 174 (for example including silicon nitride or silicon carbonitride), a third bit line spacer 176 (for example including silicon oxide or silicon oxynitride), and a fourth bit line spacer 178 (for example including silicon nitride or silicon carbonitride) stacked in sequence on the second sidewall BS2 of each bit line structure 150. The second spacer structure 140 for example includes a first gate spacer 142 (for example including silicon nitride or silicon carbonitride), a second gate spacer 144 (for example including silicon oxide or silicon oxynitride), and a third gate spacer 146 (for example including silicon nitride or silicon carbonitride) stacked in sequence on the two adjacent short sides GS1 of the two gate structure 120, but not limited thereto. The material of the first gate spacer 142 is the same as that of the second bit line spacer 174, the material of the second gate spacer 144 is the same as that of the third bit line spacer 176, and the material of the third gate spacer 146 is the same as that of the fourth bit line spacer 178. That is, the materials of the second spacer structure 140 disposed within the peripheral region 101 may be completely the same as that of the second bit line spacer structure 170 disposed within the cell region 103, as shown in FIG. 2, but not limited thereto. Also, the second spacer structure 140 is completely disposed on the shallow trench isolation 102. However, in other embodiments, the second spacer structure 240 may only include the first gate spacer 142 (for example including silicon nitride or silicon carbonitride) and the second gate spacer 144 (for example including silicon oxide or silicon oxynitride) sequentially disposed on the two adjacent sides GS1 of the two gate structures 120 as shown in FIG. 4, or only include the first gate spacer 142 (for example including silicon nitride or silicon carbonitride) disposed on the two adjacent sides GS1 of the two gate structures 120 as shown in FIG. 5, but not limited thereto. Accordingly, the material of the second spacer structure 240 disposed within the peripheral region 101 is partially the same as that of the second bit line spacer structure 170 disposed within the cell region 103.

Furthermore, the semiconductor device 10 further includes an insulating layer 180 entirely covers the substrate 100, and insulating layers 182, 184, for example each including an insulating material like silicon oxide or silicon oxynitride. The insulating layer 180 is disposed around the gate structures 120, the first spacer structure 130, the bit line structure 150, and a first gate spacer structure 160, and the insulating layer 182 is disposed between the second sidewalls BS2 of any adjacent bit line structures 150. Then, the insulating layer 184 is disposed on the insulating layer 180, also around the gate structures 120 and the first spacer structure 130. In one embodiment, the insulating layer 180, insulating layer 182, and the insulating layer 184 preferably include the same insulating material, so that, the insulating layer 184 and the insulating layer 180 underneath may be monolithic, but not limited thereto. Although omitting some components from the drawings of the present embodiment, people skilled in the art should fully understand that the semiconductor device 10 may further includes a plurality word line structures (not shown in the drawings) within the cell region and a plurality of storage node contacts (not shown in the drawings), with the word line structures being separately extending in the second direction D2 perpendicular to the bit line structures 150, and with the storage node contacts being disposed between the adjacent bit line structures 150. Then, the storage node contacts may be electrically connected to the corresponding active areas 104, for receiving or transmitting voltage signals from the substrate 100 (for example through a source or drain of a transistor component within the substrate 100). Through these arrangements, the semiconductor device 10 and a capacitor structure (not shown in the drawings) disposed above will together form a dynamic random access memory (DRAM) device, with the capacitor and the transistor component within in the substrate 100 becoming a minimum memory cell of the DRAM array to receive voltage information from the bit line structures 150 and the word line structures.

According to the semiconductor device 10 in the first embodiment of the present invention, the first spacer structure 130 and the second spacer structure 140 with different materials and/or various film structures are respectively arranged on the short side GS1 and the long side GS2 of each gate structure 120, such that, the gate structure 120 will achieve different in different extension directions of each gate structure 120. Also, the second spacer structure 140 is disposed between the two gate structures 120, simultaneously covering the adjacent short sides GS1 of the two gate structures 120 and obtaining the extending length L1 longer than the short side GS1. Accordingly, the second spacer structure 140 is allowable to effectively avoid the possible contact between the short side GS1 of each gate structure 120 and adjacent components. With these arrangements, the semiconductor device 10 enables to gain an improved component structure and better function, thereby providing better performance.

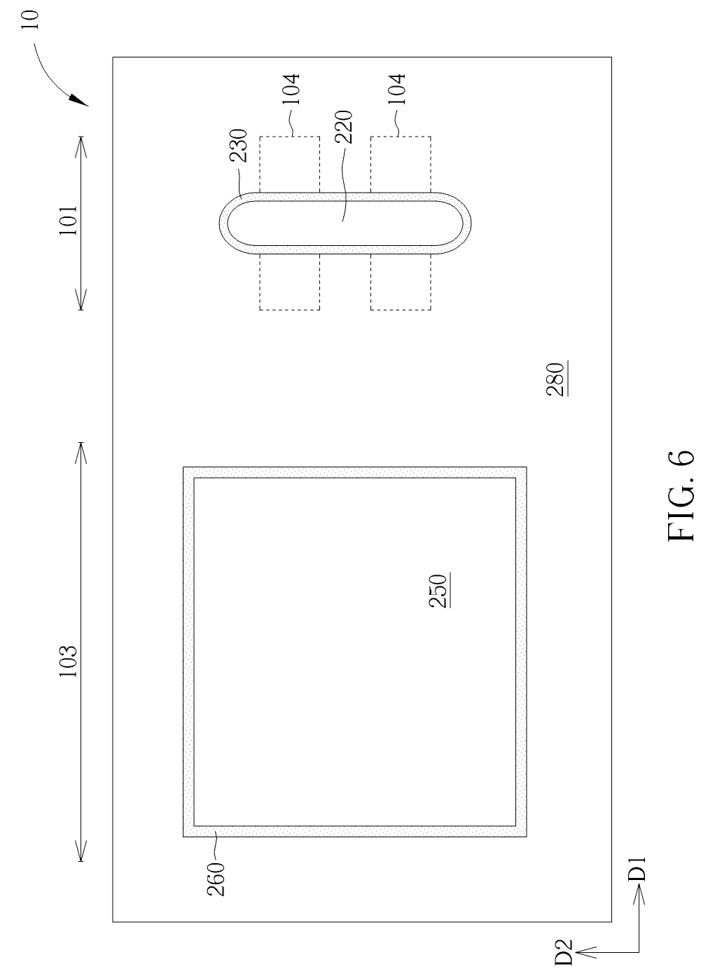

In order to make those skilled in the art easily understand the semiconductor device 10 according to the present invention, a manufacturing process of the semiconductor device 10 according to the present application will be further described hereinafter. Please refer to FIGS. 6 to 8, which are schematic diagrams illustrating a fabricating process of the semiconductor device 10 according to a preferred embodiment of the present application. First, as shown in FIG. 6, the substrate 100 is provided, and the shallow trench isolations 102 are respectively formed in the peripheral region 101 and the cell region 102 of the substrate 100, for defining the active areas 104 in the peripheral region 101 and the cell region 102. In one embodiment, the formation of the shallow trench isolations 102 is carried by firstly performing an etching process to form a plurality of trenches (not shown in the drawings) in the substrate 100, and then filling at least one insulating material like silicon oxide or silicon nitride in the trenches to form the shallow trench isolations 104, but not limited thereto. Next, a gate stacked structure 220 and a bit line stacked structure 250 are formed within the peripheral region 101 and the cell region 103 of the substrate 100, respectively, through similar processes.

Precisely speaking, before forming the gate stacked structure 220 and the bit line stacked structure 250, the silicon oxide layer 112 and the dielectric layer 110 (for example including the a silicon oxide layer 112, the silicon nitride layer 114 and the silicon oxide layer 116 stacked in sequence) is formed on the substrate 100, respectively within the peripheral region 101 and within the cell region 103. In one embodiment, a process of forming the silicon oxide layer 112 and the dielectric layer 110 includes, but are not limited to, the following steps. For example, a first oxide material layer (not shown in the drawings), a nitride material layer (not shown in the drawings) and a second oxide material layer (not shown in the drawings) stacked in sequence are sequentially formed on the substrate 100, both within the peripheral region 101 and the cell region 103, and the second oxide material layer and nitride material layer formed within the peripheral region 101 are removed. Alternatively, in another embodiment, the second oxide material layer, nitride material layer and the first oxide material layer within the peripheral region 101 are completely removed, and then another oxide layer is additionally formed.

Afterwards, a patterning process is performed through a mask layer (not shown in the drawings), partially remove the second oxide material layer, the nitride material layer and the first oxide material layer within the cell region 103, to form a plurality of openings (not shown in the drawings) partially exposing the substrate 100, in the cell region 103, thereby defining the forming positions of the bit line contacts 150C as shown in FIG. 2. The mask layer is completely removed. Next, a semiconductor material layer (not shown in the drawings, for example including a semiconductor material like doped polysilicon or doped amorphous silicon), a barrier material layer (not shown in the drawings, for example including a conductive barrier material like titanium and/or titanium nitride or tantalum and/or tantalum oxide), a metal material layer (not shown in the drawings, for example including a metal material with low resistance like tungsten, aluminum or copper), and a capping material layer (not shown in the drawings, for example including an insulating material like silicon oxide, silicon nitride or silicon oxynitride) stacked in sequence are formed on the substrate 100, both within the peripheral region 101 and the cell region 103. Another patterning process is performed through another mask layer, to partially remove the capping material layer, the metal material layer, the battier material layer, the semiconductor material layer and the first oxide material layer within the peripheral region 101, to form the gate stacked structure 220 and the silicon oxide layer 112 as shown in FIG. 2, and also, to partially remove the capping material layer, the metal material layer, the battier material layer, the semiconductor material layer, the second oxide material layer, the nitride material layer, and the first oxide material layer within the cell region 103, to form the bit line stacked structure 250 and the dielectric layer 110 as shown in FIG. 2. Then, the another mask layer is completely removed.

Further in view of FIG. 6, a deposition process and an etching back process are performed both within the peripheral region 101 and the cell region 103, to form a first gate spacer stacked structure 230 and a first bit line spacer stacked structure 260, respectively on the gate stacked structure 220 and the bit line stacked structure 250. The first gate spacer stacked structure 230 is disposed around the gate stacked structure 220, and the first bit line spacer stacked structure 260 is disposed around the bit line stacked structure 250. Then, an insulating material layer 280 is formed on the substrate 100, both within the peripheral region 101 and the cell region 103, around the first gate spacer stacked structure 230 and the first bit line spacer stacked structure 260, with the insulating material layer 280 having a top surface being coplanar with the gate stacked structure 220 and the bit line stacked structure 230. In one embodiment, the first gate spacer stacked structure 230 and the first bit line spacer stacked structure 260 each may include a monolayer structure and the same insulating material for example including silicon oxide, silicon oxynitride or silicon carbonitride, and the insulating material layer 280 may include an insulating material being different from that of the first gate spacer stacked structure 230 and the first bit line spacer stacked structure 260, preferably including silicon oxide or silicon oxynitride, but not limited thereto. In another embodiment, the first gate spacer stacked structure and the first bit line spacer stacked structure may optionally each include a multilayer structure with similar materials and similar components.

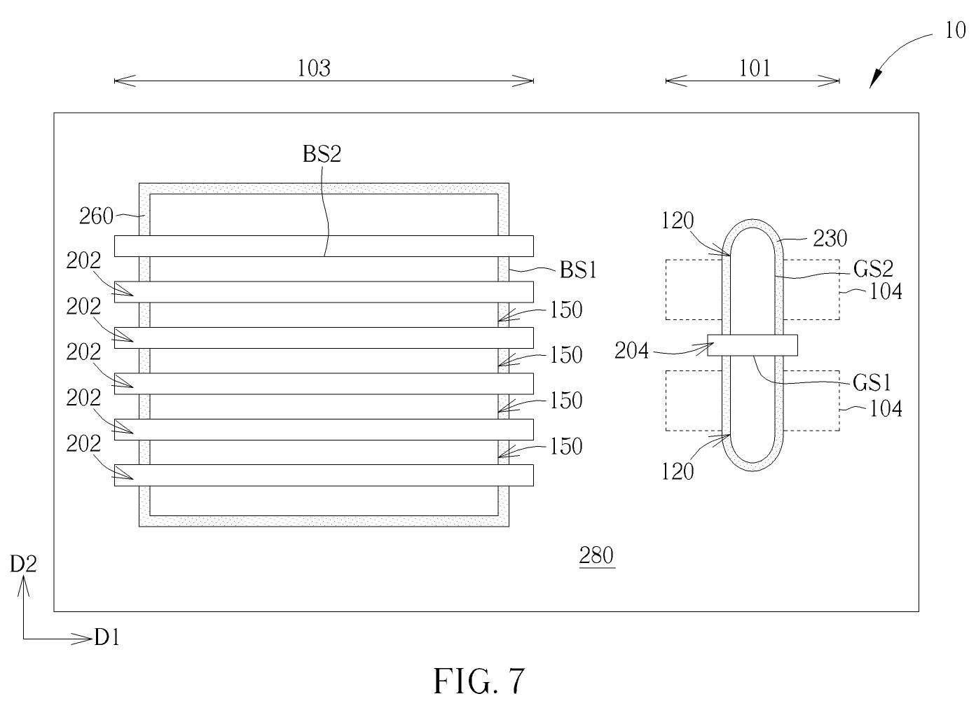

As shown in FIG. 7, a patterning process is performed through a mask layer (not shown in the drawings), to form an opening 204 and a plurality of openings 202, respectively within the peripheral region 101 and the cell region 103, and the mask layer is then removed. The opening 204 formed within the peripheral region 101cut off the gate stacked structure 220 and the first gate spacer stacked structure 230 at the same time, to form the two gate structure 220 as shown in FIG. 1 and FIG. 2. The openings 202 formed within the cell region 103 each but off the bit line stacked structure 250 and the bit line spacer stacked structure 260 at the same time, to form the bit line structures 150 as shown in FIG. 1 and FIG. 2. It is noted that, each of the gate structures 120 further includes the short side GS1 in the first direction D1 and the two long sides GS2 in the second direction D2, and each of the bit line structures 150 further includes the first sidewall BS1 in the second direction D2 and the second sidewall BS2 in the first direction D1. The first gate spacer stacked structure 230 covers the long sides GS2 of the two gate structures 120, and the first bit line spacer stacked structure 260 covers the first sidewalls BS1 of each bit line structure 150, as shown in FIG. 7

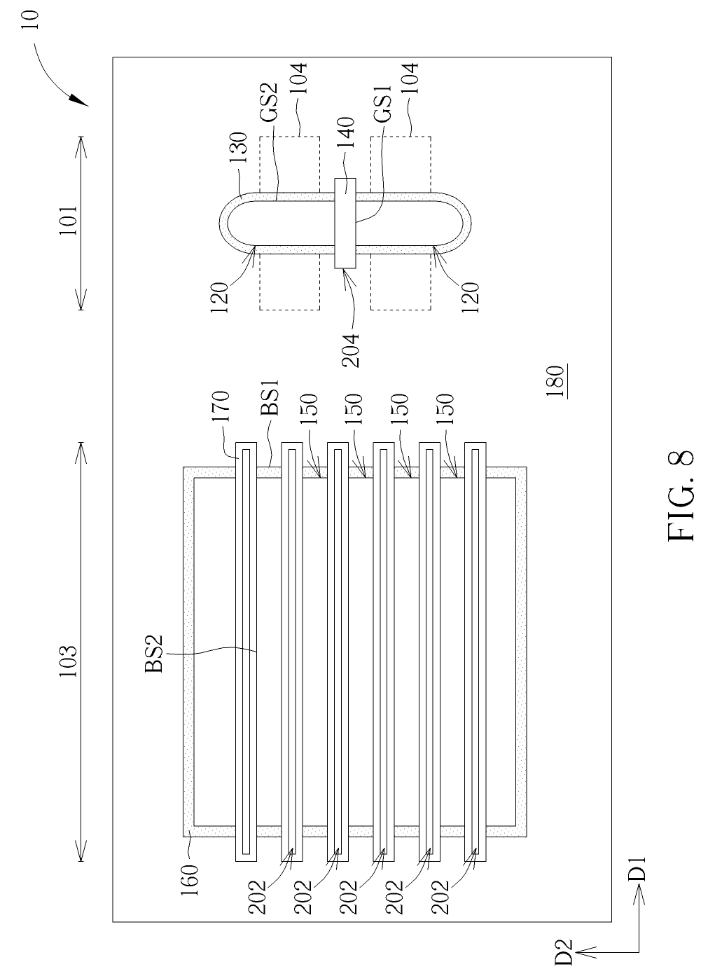

As shown in FIG. 8, plural deposition and etching back processes are performed, both within the peripheral region 101 and the cell region 103, to from the second spacer structure and the second bit line spacer structure 170, respectively in the opening 204 and the opening 202. The second spacer structure 140 filled in the opening 204, and the second bit line spacer structure 170 is formed on the sidewall of each opening 202, thereby obtain a rectangular frame structure as being viewed from a top view as shown in FIG. 8, but not limited thereto. Then, the second spacer structure 140 simultaneously covers the adjacent short side GS1 of the two gate structures 120, and the second bit line spacer structure 170 covers the second sidewall BS2 of each bit line structure 150. In one embodiment, the second bit line spacer for example includes the first bit line spacer 172 (for example including silicon nitride or silicon carbonitride) formed on the sidewall of each bit line contact 150C, and the second bit line spacer 174 (for example including silicon nitride or silicon carbonitride), the third bit line spacer 176 (for example including silicon oxide or silicon oxynitride), and the fourth bit line spacer 178 (for example including silicon nitride or silicon carbonitride) stacked in sequence on the second sidewall BS2 of each bit line structure 150, to obtain a cross-sectional structure as shown in FIG. 2. Accordingly, the second spacer structure 140 formed while forming the second bit line spacer structure 170 may optionally include the first gate spacer 142 (for example including silicon nitride and silicon carbonitride), the second gate spacer 144 (for example including silicon oxide and silicon oxynitride) and the third gate spacer 146 (for example including silicon nitride and silicon carbonitride) formed sequentially on the short side GS1 as shown in FIG. 2, or include the first gate spacer 142 (for example including silicon nitride and silicon carbonitride) and the second gate spacer 144 (for example including silicon oxide and silicon oxynitride) formed sequentially on the short side GS1 as shown in FIG. 4, or only include the first gate spacer 142 (for example including silicon nitride and silicon carbonitride) formed on the short side GS1 as shown in FIG. 5, by controlling the operating conditions of the deposition and the etching back processes, but not limited thereto.

It is also noted that, while performing the etching back process, the first gate spacer stack structure 230 being originally covered on the long sides GS2, the first bit line spacer stacked structure 260 being originally covered on the first sidewall BS1, and the insulating material layer 280 around the first gate spacer stack structure 230 and the first bit line spacer stacked structure 260 will also be partially etched, due to the difference of etching selectivity, to form the first spacer structure 130 and the insulating layer 180 as shown in FIG. 1 and FIG. 2 within the peripheral region 101. The first spacer structure 130 covers the long sides GS2 of the two gate structures 120, to obtain the first surface TS1 (as shown in FIG. 2) being slightly lower than the top surface 140t of the second spacer structure 140. The insulating layer 180 is formed around the gate structures 120 and the first spacer structure 130, and which includes a top surface (as shown in FIG. 2) being lower than the top surface 140t of the second spacer structure 140, and is coplanar with the first surface TS1.

Following these, a deposition process and a planarization process is performed within the cell region 103, to form the first bit line spacer structure 160, the insulating layer 182, and the insulating layer 184 as shown in FIG. 1 and FIG. 2, within the cell region 103. The first bit line spacer structure 160 covers the first sidewall BS1 of each bit line structure 150, the insulating layer is formed between the second sidewalls BS2 of adjacent bit line structures 150, and the insulating layer 184 is formed on the insulating layer 180, also around the gate structures 120 and the first spacer structure 130. In one embodiment, the insulating layer 180, the insulating layer 182, and the insulating layer 184 for example include the same insulating material, so that, the insulating layer 184 and the insulating layer 180 formed underneath will be monolithic, but not limited thereto. Furthermore, people skilled in the arts will fully understand that the fabricating method of the semiconductor device 10 in the present embodiment may further include forming the plurality of word line structures and the plurality of storage node contacts within the cell region 103, with the word line structures being separately extending in the second direction D2 perpendicular to the bit line structures 150, and with the storage node contacts being formed between the adjacent bit line structures 150. Then, the storage node contacts may be electrically connected to the corresponding active areas 104, for receiving or transmitting voltage signals from the substrate 100 (for example through the source or the drain of the transistor component within the substrate 100). Through these performances, the semiconductor device 10 and the capacitor structure (not shown in the drawings) subsequently formed above will together form the dynamic random access memory device, with the capacitor and the transistor component within in the substrate 100 serving as the minimum memory cell of the DRAM array to receive voltage information from the bit line structures 150 and the word line structures.

According to the fabricating method of the semiconductor device 10 in the preferred embodiment, after simultaneously forming the gate stacked structure 220 and the bit line stacked structure 250, and simultaneously forming the first gate spacer stacked structure 230 and the first bit line spacer stacked structure 260, the opening 204 is formed within the peripheral region 101 to cut off the gate stacked structure 220 and the first gate spacer stacked structure 230 at the same time, and also, the openings 202 is formed within the cell region 103 to cut off the bit line stacked structure 250 and the first bit line spacer stacked structure 260 at the same time. Then, the second spacer structure 160 and the second bit line spacer structure 170 are simultaneously formed in the opening 204 and the openings 202. With these processes, the first spacer structure 130 and the second spacer structure 140 with different materials and/or various film structures are respectively formed on the short side GS1 and the long sides GS2 of each gate structure 120 in the peripheral region 101, and the first bit line spacer structure 160 and the second bit line spacer structure 170 also with different materials and/or various film structures are respectively formed on the first sidewall BS1 and the second sidewall BS2 of each bit line structure 150 in the cell region 103, without performing additional processes. In this way, the first spacer structure 130 and the second spacer structure 140 formed on different sides will achieve different isolation effects in different extension directions of each gate structure 120, and also, the second spacer structure 160 and the second bit line spacer structure 170 formed on different sidewalls will achieve different isolation effects in different extension directions of each bit lien structure 150. Then, the semiconductor device 10 formed through the fabricating method of the present embodiment will gain an improved component structure and better function, to achieve better performance.

Those of ordinary skill in the art should easily realize the semiconductor device and the fabricating method thereof in the present disclosure are not limited to the aforementioned embodiment, and which may include other examples or varieties. The following description will detail the different embodiments of the semiconductor device and the fabricating method thereof in the present disclosure. To simplify the description, the following description will detail the dissimilarities among the different embodiments and the identical features will not be redundantly described. In order to compare the differences between the embodiments easily, the identical components in each of the following embodiments are marked with identical symbols.

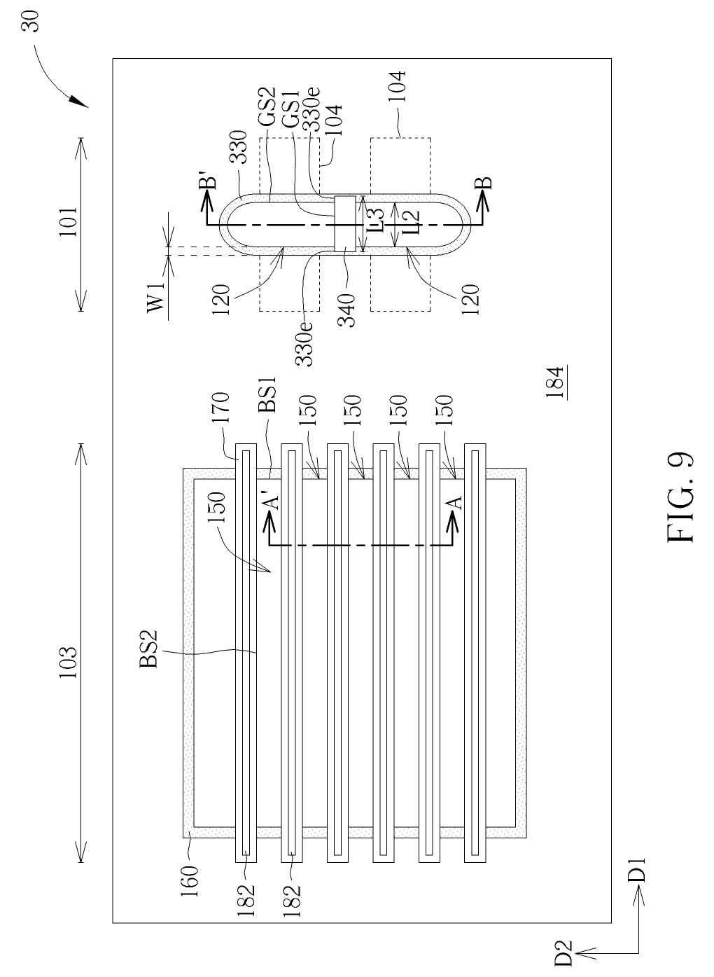

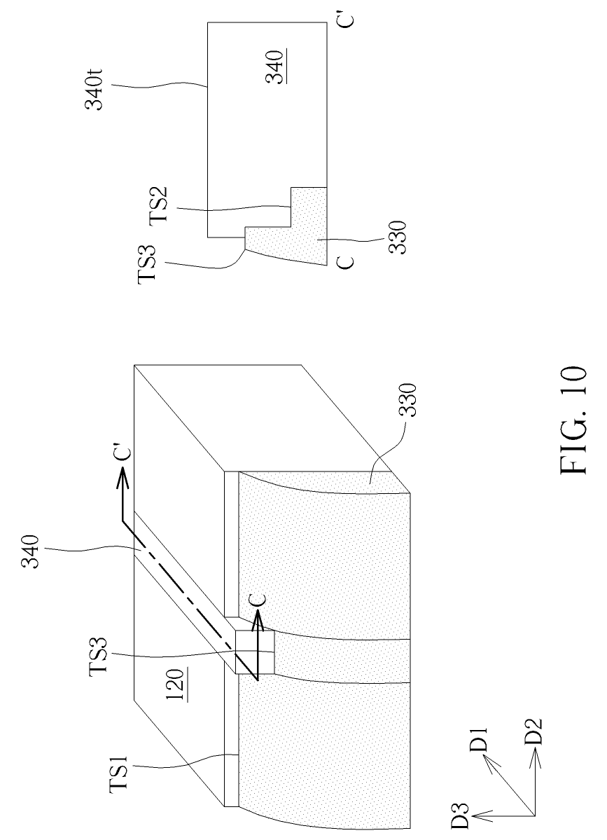

Please refer to FIG. 9 to FIG. 10, which are schematic diagrams of a semiconductor device 30 according to the second embodiment of the present disclosure, with FIG. 9 illustrating a top view of the semiconductor device 30, and with FIG. 10 both illustrating a partial three-dimensional view and a partial cross-sectional view of the semiconductor device 30. The structure of the semiconductor device 30 in the present embodiment is substantially the same as that of the semiconductor device 10, and all the similarities will not be redundantly described hereinafter. The difference between the semiconductor device 30 in the present embodiment and the semiconductor device 10 in the aforementioned embodiment is mainly in that a second spacer structure 340 in the present embodiment only partially intersects a first spacer structures 330 respectively disposed on the long sides GS2 of each gate structure 120, so that, an extending length L3 of the second spacer structure 340 in the first direction D1 is longer than the extending length L2 of the short side GS1 of the gate structure 120 in the first direction D1, but is less than the sum of the extending length L2 of the short side GS1 and two times of the width W1 of the first spacer structures 130 disposed on each long side GS2 of the gate structure 120 in the first direction D1.

In the present embodiment, the first spacer structure 330 covers the long sides GS2 of the two gate structures 120, and the second spacer structure 340 is disposed between the two gate structures 120, covering the adjacent short sides GS1 of the two gate structure 120 at the same time. It is noted that, the first spacer structure 330 covered on each long side GS2 of the gate structures 120 includes an end portion 330e in the first direction D1, and the second spacer structure 340 covers each end portion 330e of the first spacer structure 330 at the same time, as shown in FIG. 9 and FIG. 10. That is, the first spacer structure 330 respectively disposed on the long sides GS2 of the two gate structures 120 may be in direct contact with each other, so that, the first spacer structure 330 may be partially disposed below the second spacer structure 340, as shown in FIG. 10. Also, due to the difference of the etching selectivity, the first spacer structure 330 includes the first surface TS1, the second surface TS2, and a third surface TS3 with different heights in the vertical direction D3 perpendicular to the substrate 100. The first surface TS1 is higher than the second surface TS2 and the third surface TS3, and is lower than a top surface 340t of the second spacer structure 340 or the top surface 120t of the gate structure 120, and the third surface TS3 is higher than the second surface TS2, and is lower than the first surface TS1. The second surface TS2 and the third surface TS3 of the first spacer structure 330 are both disposed between the two gate structures 120, with the second surface TS2 being adjacent to the third surface TS3, below the second spacer structure 340. Accordingly, the second surface TS2 will be entirely covered by the second spacer structure 340, the third surface TS2 will be partially covered by the second spacer structure 340, and the first surface TS1 will be exposed from the second spacer structure 340, as shown in FIG. 10.

According to the semiconductor device 30 of the second embodiment, the first spacer structure 330 and the second spacer structure 340 are respectively arranged on different sides of each gate structure 120, for effectively isolating the possible contact between the different sides of each gate structure 120 in different directions and adjacent components, so that, the gate structures 120 are allowable to achieve various insulation effects in different extension directions. With these arrangements, the semiconductor device 30 enables to gain an improved component structure and better function, thereby providing better performance.

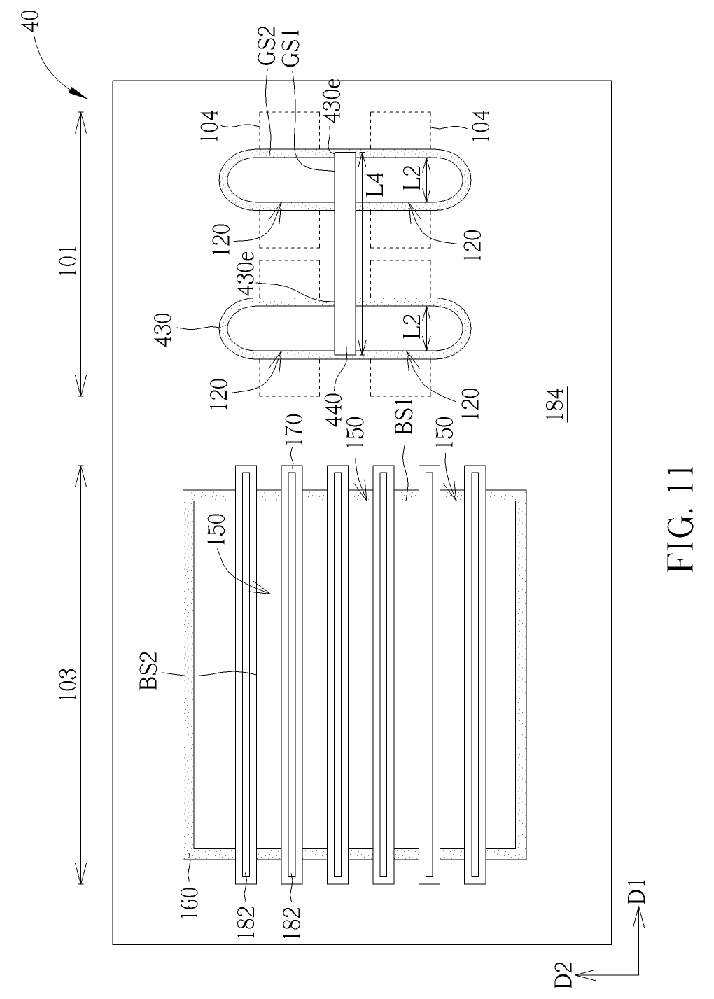

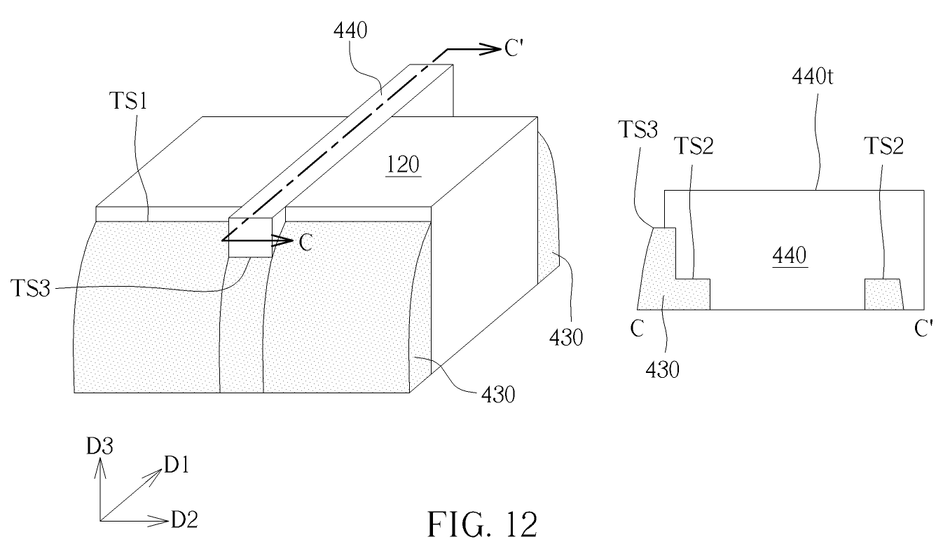

Please refer to FIG. 11 to FIG. 12, which are schematic diagrams of a semiconductor device 40 according to the third embodiment of the present disclosure, with FIG. 11 illustrating a top view of the semiconductor device 40, and with FIG. 12 both illustrating a partial three-dimensional view and a partial cross-sectional view of the semiconductor device 40. The structure of the semiconductor device 40 in the present embodiment is substantially the same as that of the semiconductor device 10, and all the similarities will not be redundantly described hereinafter. The difference between the semiconductor device 40 in the present embodiment and the semiconductor device 10 in the aforementioned embodiment is mainly in that the semiconductor device 40 includes a plurality of the gate structures 120 arranged in two rows in the first direction D1, with the gate structures 120 arranged in one row being aligned with the gate structures 120 arranged in another row in the second direction D2. Then, the short side GS1 of one gate structure 120 arranged in the one row is opposite to the short side GS1 of a corresponding gate structure 120 arranged in the another row, as shown in FIG. 11.

In the present embodiment, the first spacer structure 430 covers the long sides GS2 of each gate structure 120, and the second spacer structure 440 is disposed between the gate structures 120 arranged in the two rows, covering the short side GS1 of each gate structure 120. It is noted that, the first spacer structure 430 covered on each long side GS2 of the gate structures 120 includes an end portion 430e in the first direction D1, and the second spacer structure 440 of the present embodiment covers a portion of the end portion 430e of the first spacer structure 430, and partially covers another portion of the end portion 430e, as shown in FIG. 11 and FIG. 12. That is, the second spacer structure 440 partially intersects the first spacer structure 430 disposed on one long side GS2 of a corresponding gate structure 120, and fully intersects the first spacer structure 430 disposed on another long side GS2 of the corresponding gate structure 120, to further extend to intersect the first spacer structure 430 disposed on one long side GS2 of another corresponding gate structure 120. In this way, an extending length L4 of the second spacer structure 440 in the first direction D1 will be at least longer than two times of the extending length L2 of the short side GS1 in the first direction D1, as shown in FIG. 11.

It is also noted that, the first spacer structure 430 respectively disposed on the long sides GS2 of two gate structures 120 in alignment with each other in the two row, may be in direct contact with each other, so that, a portion of the first spacer structure 430 will be disposed below the second spacer structure 440, as shown in FIG. 12. Furthermore, due to the difference of the etching selectivity, the first spacer structure 430 includes the first surface TS1, the second surface TS2, and the third surface TS3 with different heights in the vertical direction D3 perpendicular to the substrate 100. The first surface TS1, the second surface TS2, and the third surface TS3 are all lower than the top surface 440t of the second spacer structure 440, with the first surface TS1 being higher than the second surface TS2 and the third surface TS3, and with the third surface TS3 being higher than the second surface TS2 and lower than the first surface TS1. Precisely speaking, the third surface TS3 and the second surface TS2 of the first spacer structure 430 are both disposed between the two gate structures 120 in alignment with each other in the second direction D2. The second spacer structure 440 covers the second surface TS2, and partially covers the third surface TS3, with the first surface TS1 being exposed therefrom, as shown in FIG. 12.

According to the semiconductor device 40 of the second embodiment, the first spacer structure 430 and the second spacer structure 440 are respectively arranged on different sides of each gate structure 120, for effectively isolating the possible contact between the different sides of each gate structure 120 in different directions and adjacent components, so that, the gate structures 120 are allowable to achieve various insulation effects in different extension directions. With these arrangements, the semiconductor device 40 enables to gain an improved component structure and better function, thereby providing better performance.

Overall speaking, through the present invention, the fabrications of components within different regions are integrated, to form gate spacer structure with different materials and/or various film structures on different sides of each gate structure, while forming the bit line spacer structure. Then, the gate structure will be allowable to achieve different insulation effects in different extension directions. Accordingly, the semiconductor device fabricated through the fabricating process of the present invention will therefore gain an improved component structure and better function, so as to achieve better operating performance.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate;
at least two gate structures, disposed on the substrate and each comprising a short side extending in a first direction and a long side extending in a second direction, wherein the short side of the at least two gate structures is opposite to each other, and the first direction is perpendicular to the second direction;
a first spacer structure, covering the long side of each of the at least two gate structures; and
a second spacer structure, covering the short side of each of the at least two gate structures, wherein an extending length of the second spacer structure in the first direction is longer than an extending length of the short side of each of the at least two gate structures in the first direction.

2. The semiconductor device according to claim 1, further comprising:
a plurality of bit line structures, separately extending in the first direction and disposed on the substrate, each of the bit line structures comprising a first sidewall in the second direction and a second sidewall in the first direction;
a first bit line spacer structure, covering the first sidewall of each of the bit line structure; and
a second bit line spacer structure, covering the second sidewall of each of the bit line structure, wherein the second bit line spacer structure comprises a first bit line spacer, a second bit line spacer, and a third bit line spacer disposed in sequence.

3. The semiconductor device according to claim 2, wherein a material of the second spacer structure is the same as a material of at least a portion of the second bit line spacer structure.

4. The semiconductor device according to claim 2, wherein a material of the first spacer structure is the same as a material of the first bit line spacer structure.

5. The semiconductor device according to claim 1, wherein portions of the first spacer structure covering on the long side of the at least two gate structures are opposite with each other, and each of the portions comprises an end portion in the first direction, and the second spacer structure covers the end portion.

6. The semiconductor device according to claim 1, wherein the first spacer structure covering on the long side of the at least two gate structures comprises a first surface and a second surface in different heights, and the second spacer structure covers the second surface.

7. The semiconductor device according to claim 6, wherein the first surface is higher than second surface, and is lower than a top surface of the second spacer structure.

8. The semiconductor device according to claim 1, wherein the extending length of the second spacer structure is larger than a sum of the extending length of the short side of the at least two gate structures and two times width of the first spacer structure in the first direction.

9. The semiconductor device according to claim 7, wherein the first spacer structure covering on the long side of the at least two gate structures comprises a third surface, and a height of the third surface is different from that of the second surface and the first surface.

10. The semiconductor device according to claim 9, wherein the third surface is higher than the second surface, and is lower than the first surface.

11. The semiconductor device according to claim 9, wherein the first spacer structure partially covers an end portion of the second spacer structure in the second direction.

12. The semiconductor device according to claim 1, wherein the at least two gate structures further comprise:
a plurality of the gate structures, the short sides of two corresponding ones of the plurality of the gate structures are opposite to each other, and the second spacer structure covers the short side of each of the plurality of the gate structures.

13. The semiconductor device according to claim 12, wherein portions of the first spacer structure covering on the long side of the at least two gate structures are opposite to each other, and each comprises an end portion in the first direction, the second spacer structure covers the end portion, and the first spacer structure covering on the long side of the at least two gate structures comprises a first surface and a second surface in different heights, the first surface is higher than the second surface and is lower than a top surface of the second spacer structure, and the second spacer structure covers the second surface.

14. A method of fabricating a semiconductor device, comprising:
providing a substrate;
forming at least two gate structures on the substrate, each comprising a short side extending in a first direction and a long side extending in a second direction, wherein the short side of each of the at least two gate structures is opposite with each other, and the first direction is perpendicular to the second direction;
forming a first spacer structure on the long side of each of the at least two gate structures; and
forming a second spacer structure on the short side of each of the at least two gate structures, wherein an extending length of the second spacer structure in the first direction is longer than an extending length of the short side of each of the at least two gate structures in the first direction.

15. The method of fabricating the semiconductor device according to claim 14, forming the gate structure further comprising:
forming a gate stacked structure on the substrate;
forming a first gate spacer stacked structure surrounding the gate stacked structure;
forming an insulating layer, surrounding the first gate spacer stacked structure and the gate stacked structure; and
performing a patterning process, cutting off the gate stacked structure to form the at least two gate structures.

16. The method of fabricating the semiconductor device according to claim 15, while performing the patterning process, partially cutting off the first gate spacer stacked structure to form the first spacer structure.

17. The method of fabricating the semiconductor device according to claim 15, further comprising:
forming a bit line stacked structure on the substrate;
while forming the first gate spacer stacked structure, simultaneously forming a first bit line spacer stacked structure surrounding the bit line stacked structure; and
while performing the patterning process, patterning the bit line stacked structure, to form a plurality of bit line structures separately extending in the first direction.

18. A semiconductor device, comprising:
a substrate, comprising a first active area in a cell region and a second active area in a peripheral region;
a plurality of bit line structures, disposed on the first active area, separately extending in a first direction and arranging in a second direction perpendicular to the first direction;
a first bit line spacer structure, covering a first sidewall of each of the bit line structure in the second direction;
a second bit line spacer structure, covering a second sidewall of each of the bit line structure in the first direction;
at least two gate structures, disposed on the second active area and each comprising a short side extending in a first direction and a long side extending in a second direction, wherein the short side of the at least two gate structures is opposite to each other;
a first spacer structure, covering the long side of each of the at least two gate structures; and
a second spacer structure, simultaneously covering the short side of each of the at least two gate structures, wherein a material of the second spacer structure is the same as a material of at least a portion of the second bit line spacer structure, and a material of the first spacer structure is the same as a material of the first bit line spacer structure.

19. The semiconductor device according to claim 18, wherein the first spacer structure covering on the long side of the at least two gate structures comprises a first surface and a second surface, the first surface is higher than second surface, and is lower than a top surface of the second spacer structure, and the second spacer structure covers the second surface.

20. The semiconductor device according to claim 18, wherein the first spacer structure covering on the long side of the at least two gate structures comprises a third surface, and a height of the third surface is different from that of the second surface and the first surface.
